(19) United States
(12) Patent Application Publication
(10) Pub. No.: US 2019/0148325 A1
(43) Pub. Date: May 16, 2019

(54) ELECTRONIC DEVICE AND METHOD FOR MANUFACTURING THE SAME

(71) Applicant: Advanced Semiconductor Engineering, Inc., Kaohsiung (TW)

(72) Inventors: Wen-Long LU, Kaohsiung (TW); Chi-Chang LEE, Kaohsiung (TW)

(73) Assignee: Advanced Semiconductor Engineering, Inc., Kaohsiung (TW)

(21) Appl. No.: 15/809,674

(22) Filed: Nov. 10, 2017

(51) Int. Cl. H01L 23/00; H01L 21/683

(52) U.S. Cl. CPC H01L 24/13; H01L 2224/1357; H01L 24/03; H01L 24/05; H01L 21/6835; H01L 2224/02331; H01L 2224/05024; H01L 2224/05017; H01L 2224/05008; H01L 2924/2064; H01L 2224/0231; H01L 2221/6835; H01L 2224/1134; H01L 2224/0381; H01L 2224/0401; H01L 2224/13017; H01L 2224/13551; H01L 2224/13023; H01L 2224/11001; H01L 2224/13024; H01L 2924/3512; H01L 2224/0239; H01L 2924/01022; H01L 2924/01029; H01L 2224/05147; H01L 2224/05144; H01L 2224/04105; H01L 2224/12105; H01L 2224/03462; H01L 2224/13147; H01L 2224/13144; H01L 2224/13582; H01L 2224/1146; H01L 2224/13611; H01L 2224/13639; H01L 2224/11849; H01L 24/11

(57) ABSTRACT

An electronic device includes a dielectric layer, a redistribution layer, a conductive structure, an insulating layer and a solder bump. The dielectric layer has a first surface and a second surface opposite to the first surface, and defines a through hole extending between the first surface and the second surface. The redistribution layer is disposed on the first surface of the dielectric layer and in the through hole. The conductive structure is disposed on the redistribution layer. The conductive structure includes an upper portion and a lower portion. The lower portion is disposed on the redistribution layer, and the upper portion is disposed on the lower portion. The insulating layer covers a portion of the redistribution layer and surrounds a first portion of the lower portion of the conductive structure. The solder bump covers a portion of the conductive structure.

### BACKGROUND

### 1. Field of the Disclosure

The present disclosure relates to an electronic device and a manufacturing method, and to an electronic device having a conductive structure partially covered by an insulating layer, and a method for manufacturing the electronic device.

### 2. Description of the Related Art

In a semiconductor package with input/output (I/O) pins, a coefficient of thermal expansion (CTE) of its components (e.g., a chip, a solder, an insulating layer and a substrate) can be different from each other, thus resulting in CTE mismatch. Hence, after high-temperature processes, shear stress may occur during cooling of such a semiconductor. Among these components, the solder, which can be mainly composed of tin, has a relatively low mechanical strength and poor tolerance of shear stress, and may readily crack at a soldering interface with the insulating layer. Accordingly, a failure rate of I/O pins is large, resulting in poor reliability.

### SUMMARY

In some embodiments, an electronic device includes a dielectric layer, a redistribution layer, a conductive structure, an insulating layer and a solder bump. The dielectric layer has a first surface and a second surface opposite to the first surface, and defines a through hole extending between the first surface and the second surface. The redistribution layer is disposed on the first surface of the dielectric layer and in the through hole. The conductive structure is disposed on the redistribution layer. The conductive structure includes an upper portion and a lower portion. The lower portion is disposed on the redistribution layer, and the upper portion is disposed on the lower portion. The insulating layer covers a portion of the redistribution layer and a surrounds a first portion of the lower portion of the conductive structure. The solder bump covers a portion of the conductive structure.

In some embodiments, a method for manufacturing an electronic device includes (a) forming a dielectric layer; (b) forming a redistribution layer on the dielectric layer; (c) forming a conductive structure on the redistribution layer; (d) forming an insulating layer to cover the conductive structure and the redistribution layer, wherein a portion of the conductive structure is exposed from the insulating layer; and (e) forming a solder bump on the exposed portion of the conductive structure.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross sectional view of an example of an electronic device according to some embodiments of the present disclosure.

FIG. 2 illustrates an enlarged view of an area “A” shown in FIG. 1.

FIG. 3 illustrates a cross sectional view of an example of an electronic device according to some embodiments of the present disclosure.

FIG. 4 illustrates a cross sectional view of an example of an electronic device according to some embodiments of the present disclosure.

FIG. 5 illustrates an enlarged view of an area “B” shown in FIG. 4.

FIG. 6 illustrates a cross sectional view of an example of an electronic device according to some embodiments of the present disclosure.

FIG. 7 illustrates a cross sectional view of an example of an electronic device according to some embodiments of the present disclosure.

FIG. 8 illustrates a cross sectional view of an example of an electronic device according to some embodiments of the present disclosure.

FIG. 9 illustrates one or more stages of an example of a method for manufacturing an electronic device according to some embodiments of the present disclosure.

FIG. 10 illustrates a schematic perspective view of an example of a combination of a base material, a pad and a dielectric layer depicted in FIG. 9.

FIG. 11 illustrates a schematic perspective view of an example of a combination of a base material, a pad and a dielectric layer depicted in FIG. 9.

FIG. 12 illustrates one or more stages of an example of a method for manufacturing an electronic device according to some embodiments of the present disclosure.

FIG. 13 illustrates one or more stages of an example of a method for manufacturing an electronic device according to some embodiments of the present disclosure.

FIG. 14 illustrates one or more stages of an example of a method for manufacturing an electronic device according to some embodiments of the present disclosure.

FIG. 15 illustrates one or more stages of an example of a method for manufacturing an electronic device according to some embodiments of the present disclosure.

FIG. 16 illustrates one or more stages of an example of a method for manufacturing an electronic device according to some embodiments of the present disclosure.

FIG. 17 illustrates one or more stages of an example of a method for manufacturing an electronic device according to some embodiments of the present disclosure.

FIG. 18 illustrates one or more stages of an example of a method for manufacturing an electronic device according to some embodiments of the present disclosure.

FIG. 19 illustrates one or more stages of an example of a method for manufacturing an electronic device according to some embodiments of the present disclosure.

FIG. 20 illustrates one or more stages of an example of a method for manufacturing an electronic device according to some embodiments of the present disclosure.

FIG. 21 illustrates one or more stages of an example of a method for manufacturing an electronic device according to some embodiments of the present disclosure.

FIG. 22 illustrates one or more stages of an example of a method for manufacturing an electronic device according to some embodiments of the present disclosure.

FIG. 23 illustrates one or more stages of an example of a method for manufacturing an electronic device according to some embodiments of the present disclosure.

FIG. 24 illustrates one or more stages of an example of a method for manufacturing an electronic device according to some embodiments of the present disclosure.

FIG. 25 illustrates one or more stages of an example of a method for manufacturing an electronic device according to some embodiments of the present disclosure.

FIG. 26 illustrates one or more stages of an example of a method for manufacturing an electronic device according to some embodiments of the present disclosure.

FIG. 27 illustrates one or more stages of an example of a method for manufacturing an electronic device according to some embodiments of the present disclosure.

FIG. 28 illustrates one or more stages of an example of a method for manufacturing an electronic device according to some embodiments of the present disclosure.

FIG. 29 illustrates one or more stages of an example of a method for manufacturing an electronic device according to some embodiments of the present disclosure.

FIG. 30 illustrates one or more stages of an example of a method for manufacturing an electronic device according to some embodiments of the present disclosure.

FIG. 31 illustrates one or more stages of an example of a method for manufacturing an electronic device according to some embodiments of the present disclosure.

FIG. 32 illustrates one or more stages of an example of a method for manufacturing an electronic device according to some embodiments of the present disclosure.

FIG. 33 illustrates one or more stages of an example of a method for manufacturing an electronic device according to some embodiments of the present disclosure.

FIG. 34 illustrates one or more stages of an example of a method for manufacturing an electronic device according to some embodiments of the present disclosure.

FIG. 35 illustrates one or more stages of an example of a method for manufacturing an electronic device according to some embodiments of the present disclosure.

FIG. 36 illustrates one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for an electronic device including a conductive structure disposed on a redistribution layer and partially covered by an insulating layer, and a solder bump covering a portion of the conductive structure. At least some embodiments of the present disclosure provide for techniques for manufacturing the electronic device.

In a comparative semiconductor package, a solder ball is directly disposed on and contacts a bump pad of a redistribution layer, and an insulating layer may cover the redistribution layer and contact the solder ball. Since the solder ball is mainly composed of tin (e.g. is over 50% tin by weight), a bonding strength between the solder ball and the bump pad, and a bonding strength between the solder ball and the insulating layer may be weak. Hence, when a shear stress parallel to an upper surface of the insulating layer occurs due to CTE mismatch, the solder ball may readily crack at a soldering interface with the insulating layer, resulting in an open circuit between the solder ball and the bump pad. When a ball shear test is applied to evaluate the reliability of the solder ball, a shear tool moves along a direction parallel to the upper surface of the insulating layer, and pushes the solder ball so as to apply a shear force to break the solder ball (e.g. to detach the solder ball from the insulating layer). The testing result shows that when the bonding area is about 700 square micrometers (μm²), a shear force that can break the solder ball is about 5.5 pounds. That is, the ability of the solder ball to resist the shear force is low. One reason for the low resistance to the shear force is the formation of an intermetallic compound (IMC) between the solder ball and the redistribution layer. Another reason is that there may be space or gap between the solder ball and the insulating layer, and the insulating layer cannot hold the solder ball securely.

The present disclosure provides for an electronic device including a conductive structure to address at least the above concerns. In some embodiments, a conductive structure is disposed on a redistribution layer and partially covered by an insulating layer. A solder bump covers a portion of the conductive structure. The conductive structure connects a solder bump and the redistribution layer, and the solder bump and the insulating layer, thus providing improved tolerance of shear stress.

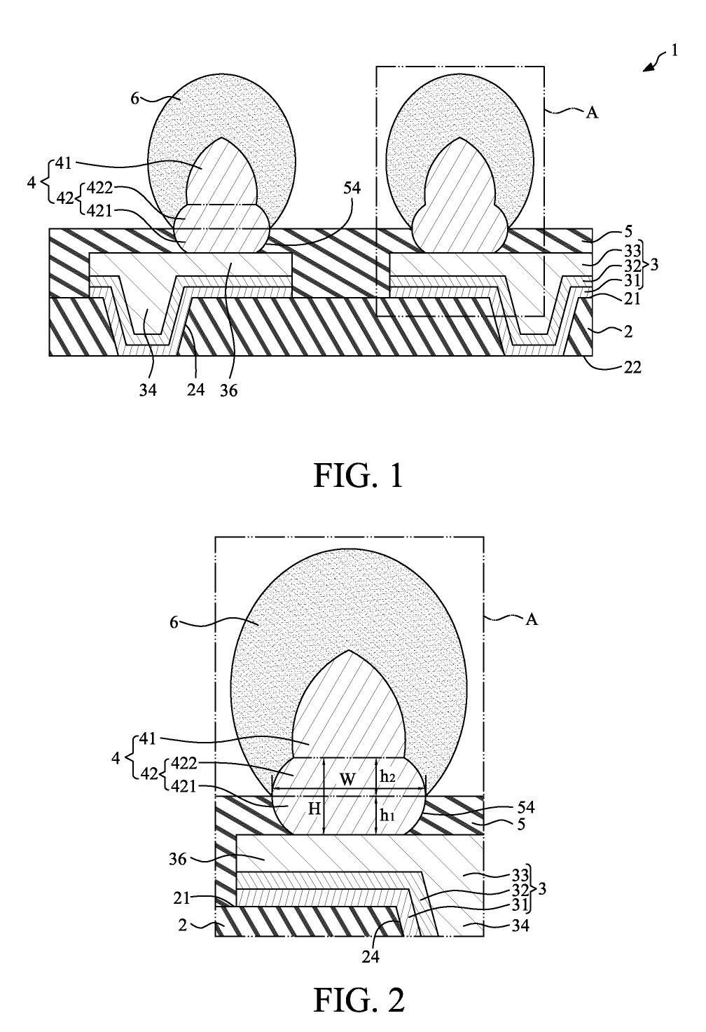

FIG. 1 illustrates a cross sectional view of an electronic device 1 according to some embodiments of the present disclosure. FIG. 2 illustrates an enlarged view of an area “A” shown in FIG. 1. The electronic device 1 includes a dielectric layer 2, a redistribution layer 3, a conductive structure 4, an insulating layer 5 and a solder bump 6 (e.g., a solder ball).

The dielectric layer 2 has a first surface 21 and a second surface 22 opposite to the first surface 21. The dielectric layer 2 defines a through hole 24 extending between the first surface 21 and the second surface 22. The dielectric layer 2 may include an insulating material, a dielectric material or a solder resist material, such as, for example, benzocyclobutene (BCB) based polymer or a polyimide (PI).

The redistribution layer (RDL) 3 is disposed on the first surface 21 of the dielectric layer 2 and in the through hole 24 of the dielectric layer 2. For example, the redistribution layer 3 may include a first metal layer 31, a second metal layer 32 and a third metal layer 33 disposed in that order on the dielectric layer 2. The first metal layer 31 and the second metal layer 32 may be seed layers including, for example, titanium and/or copper, another metal, or an alloy, and may be formed or disposed by sputtering. For example, the first metal layer 31 may include titanium, and the second metal layer 32 may include copper. The third metal layer 33 may include, for example, copper, or another metal or combination of metals, and may be formed or disposed by electroplating. In some embodiments, as shown in FIG. 1, the redistribution layer 3 may include a conductive via 34 and a bump pad 36. The conductive via 34 may be disposed in the through hole 24. The bump pad 36 may be disposed on the second surface 22 of the dielectric layer 2 and electrically connected to the conductive via 34. The conductive via 34 and the bump pad 36 may be formed concurrently or integrally (e.g. as a monolithic structure).

The conductive structure 4 is disposed on the bump pad 36 of the redistribution layer 3. A material of the conductive structure 4 (that is, a material included in the conductive structure 4) may be a conductive metal, such as, for example, copper and/or gold, or another metal or combination of metals, and may be formed or disposed by a wire-bonding process. The conductive structure 4 includes an upper portion 41 and a lower portion 42. The lower portion 42 is disposed on the redistribution layer 3, and the upper portion 41 is disposed on and connected to the lower portion 42. For example, the lower portion 42 of the conductive structure 4 is disposed on and contacts the redistribution layer 3. In some embodiments, the conductive structure 4 is a monolithic structure without a boundary between the upper portion 41 and the lower portion 42 thereof. A volume of the lower portion 42 may be greater than a volume of the upper portion 41 (e.g., may be about 1.1 or more times greater, about 1.2 or more times greater, about 1.3 or more times greater, or about 1.4 or more times greater). In some embodiments, the upper portion 41 is substantially in a cone shape (e.g. a cone having a convex side wall that bulges outwards), the lower portion 42 is substantially in a disk or puck shape (e.g. a puck that has a convex side wall that bulges outwards), and a curvature of the side wall of the upper portion 41 and a curvature of the side wall of the lower portion 42 are discontinuous at an intersection therebetween. For example, the conductive structure 4 may be a stub bump, and the upper portion 41 and the lower portion 42 thereof may respectively be the stud portion and the bump portion of the stud bump. In some embodiments, the lower portion 42 of the conductive structure 4 may include a first portion 421 and a second portion 422. The first portion 421 and the second portion 422 may be divided by an imaginary plane defined by the top surface of the insulating layer 5. The first portion 421 may be embedded in the insulating layer 5, and the imaginary plane dividing the first portion 421 and the second portion 422 may be substantially coplanar with the top surface of the insulating layer 5. The second portion 422 may be disposed on the first portion 421 at a higher elevation than the top surface of the insulating layer 5.

The insulating layer 5 is disposed on the dielectric layer 2. The insulating layer 5 may include an insulating material, such as, for example, BCB based polymer or a PI. In some embodiments, the insulating layer 5 may include cured photoimageable dielectric (PID) material such as an epoxy or a PI including photoinitiators. The insulating layer 5 covers a portion of the redistribution layer 3 and surrounds the first portion 421 of the lower portion 42 of the conductive structure 4. For example, the insulating layer 5 defines an accommodating cavity 54 for accommodating the first portion 421 of the lower portion 42 of the conductive structure 4, and a profile of the accommodating cavity 54 is conformal to the first portion 421 of the lower portion 42 of the conductive structure 4. The insulating layer 5 may be formed or disposed after the formation of the conductive structure 4 to be conformal with the first portion 421 of the lower portion 42 of the conductive structure 4. The insulating layer 5 may contact the first portion 421 of the lower portion 42 of the conductive structure 4. For example, the first portion 421 of the lower portion 42 of the conductive structure 4 is embedded in the insulating layer 5.

The solder ball 6 covers a portion of the conductive structure 4. For example, as shown in FIG. 1, the solder ball 6 covers the upper portion 41 of the conductive structure 4, and the second portion 422 of the lower portion 42 of the conductive structure 4. A material of the solder ball 6 may be a conductive metal, such as, for example, tin and/or silver, or another metal or combination of metals. The material of the solder ball 6 may be different from the material of the conductive structure 4. In some embodiments, the solder ball 6 does not contact the insulating layer 5. In addition, the solder ball 6 does not contact the first portion 421 of the lower portion 42 of the conductive structure 4. The solder ball 6 does not cover the entire conductive structure 4.

Referring to FIG. 2, which shows an enlarged view of a region “A” shown in FIG. 1, a maximum width “W” of the lower portion 42 of the conductive structure 4 is in a range of about 15 micrometer (μm) to about 70 μm, such as about 20 μm to about 65 μm, about 30 μm to about 55 μm, or about 40 μm to about 55 μm. A height “H” of the lower portion 42 of the conductive structure 4 may be in a range of about 6.4 μm to about 30 μm, such as about 10 μm to about 25 μm, or about 15 μm to about 20 μm. In some embodiments, a ratio of the maximum width “W” of the lower portion 42 of the conductive structure 4 to the height “H” of the lower portion 42 of the conductive structure 4 is in a range of about 1.5 to about 3, such as about 1.8 to about 2.5, or about 2 to about 2.3.

The first portion 421 of the lower portion 42 of the conductive structure 4 surrounded by the insulating layer 5 has a height h₁. The height h₁ of the first portion 421 of the lower portion 42 of the conductive structure 4 surrounded by the insulating layer 5 is equal to or greater than about a half of the height “H” of the lower portion 42 of the conductive structure 4. The second portion 422 of the lower portion 42 of the conductive structure 4 covered by the solder ball 6 has a height h₂. The height h₂ of the second portion 422 of the lower portion 42 of the conductive structure 4 (e.g. the second portion 422 of the lower portion 42 of the conductive structure 4 covered by the solder ball 6) is equal to or less than about a half of the height “H” of the lower portion 42 of the conductive structure 4. As shown in FIG. 2, the height h₁ of the first portion 421 of the lower portion 42 of the conductive structure 4 surrounded by the insulating layer 5 plus the height h₂ of the second portion 422 of the lower portion 42 of the conductive structure 4 covered by the solder ball 6 may be about equal to the height “H” of the lower portion 42 of the conductive structure 4.

In the electronic device 1, the conductive structure 4 connects the solder ball 6 and the redistribution layer 3 (e.g. electrically and/or physically connects), and physically connects the solder ball 6 and the insulating layer 5. The conductive structure 4 provides for a resistance of shear stress stronger than that of a solder ball directly disposed on and contacting a redistribution layer and covered by an insulating layer. When a ball shear test is applied to evaluate the reliability of the conductive structure 4 and the solder ball 6, a shear tool moves along a direction parallel to the top surface of the insulating layer 5, and pushes the second portion 422 of the lower portion 42 of the conductive structure 4, the upper portion 41 of the conductive structure 4 and the solder ball 6 so as to apply a shear force to break the conductive structure 4. The testing result shows that when the bonding area is about 700 μm², a shear force that can break the conductive structure 4 is about 44 pounds. That is, the ability that the conductive structure 4 to resist the shear force is relatively high, compared to some comparative implementations. One reason for the high resistance to the shear force is that an IMC will not be readily formed between the conductive structure 4 and the redistribution layer 3. Another reason is that there is no space nor gap between the first portion 421 of the lower portion 42 of the conductive structure 4 and the insulating layer 5 (e.g. the first portion 421 of the lower portion 42 of the conductive structure 4 and the insulating layer 5 can be in direct contact), and the insulating layer 5 can hold the conductive structure 4 securely.

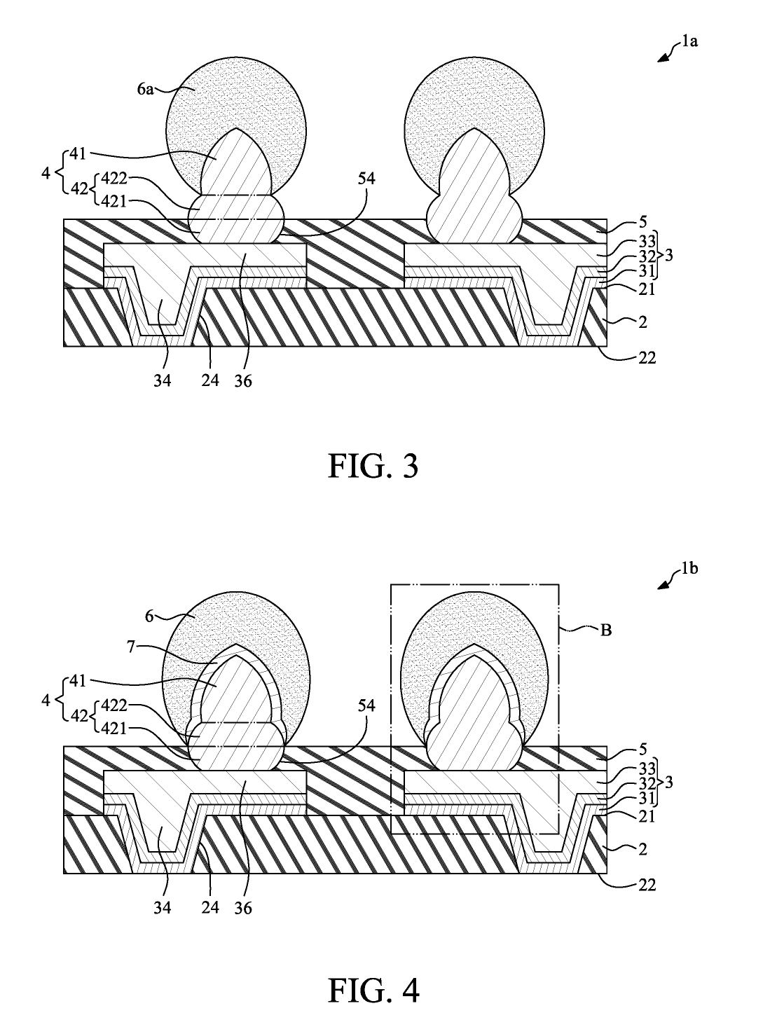

FIG. 3 illustrates a cross sectional view of an electronic device 1a according to some embodiments of the present disclosure. The electronic device 1a is similar to the electronic device 1 shown in FIG. 1 and FIG. 2, except that the solder ball 6a shown in FIG. 3 selectively covers the upper portion 41 of the conductive structure 4, and leaves the lower portion 42 of the conductive structure 4 exposed.

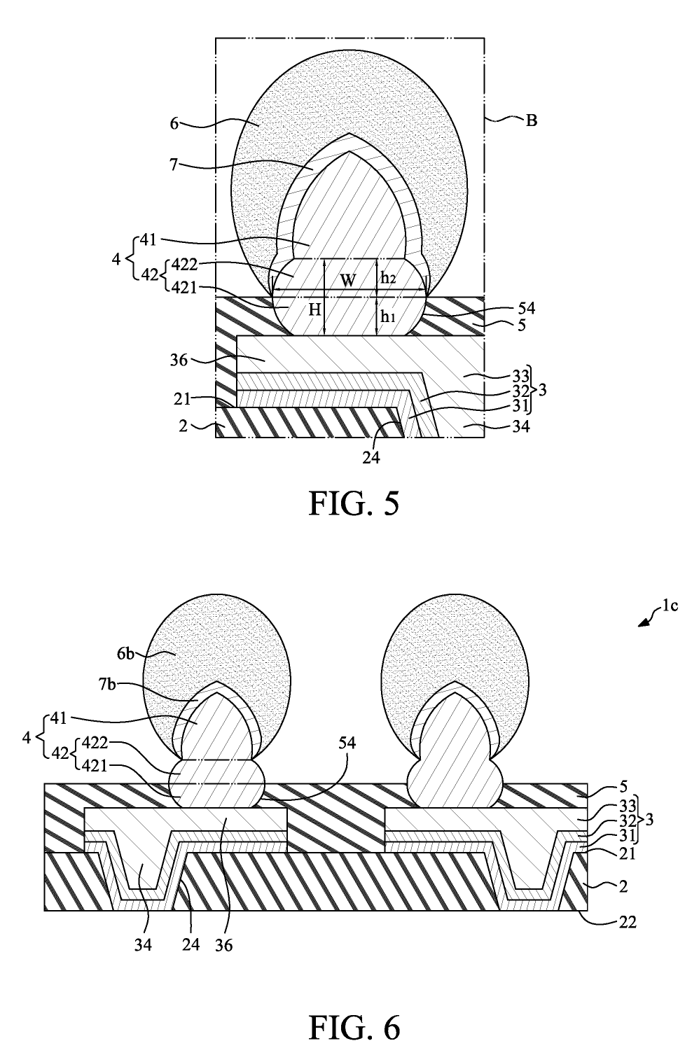

FIG. 4 illustrates a cross sectional view of an electronic device 1b according to some embodiments of the present disclosure. FIG. 5 illustrates an enlarged view of an area “B” shown in FIG. 4. The electronic device 1b is similar to the electronic device 1 shown in FIG. 1 and FIG. 2, except that the electronic device 1b shown in FIG. 4 and FIG. 5 further includes a seed layer 7 covering a portion of the conductive structure 4.

In some embodiments, the seed layer 7 covers the upper portion 41 of the conductive structure 4 and the second portion 422 of the lower portion 42 of the conductive structure 4. As shown in FIG. 4, the seed layer 7 covers the second portion 422 of the lower portion 42 of the conductive structure 4, and the second portion 422 is also covered by the solder ball 6. For example, the seed layer 7 is disposed between the solder ball 6 and the conductive structure 4, and is covered (e.g. completely covered) by the solder ball 6.

In the electronic device 1b, since the seed layer 7 covers the conductive structure 4, bonding strength between the solder ball 6 and the conductive structure 4 can be enhanced. Additionally, the seed layer 7 may fix the position and the shape of the solder ball 6, preventing the solder ball 6 from contacting the insulating layer 5.

FIG. 6 illustrates a cross sectional view of an electronic device 1c according to some embodiments of the present disclosure. The electronic device 1c is similar to the electronic device 1b shown in FIG. 4 and FIG. 5, except that the seed layer 7b shown in FIG. 6 selectively covers the upper portion 41 of the conductive structure 4, and leaves the lower portion 42 of the conductive structure 4 exposed. Similarly, the solder ball 6b shown in FIG. 6 selectively covers the upper portion 41 of the conductive structure 4, and leaves the lower portion 42 of the conductive structure 4 exposed.

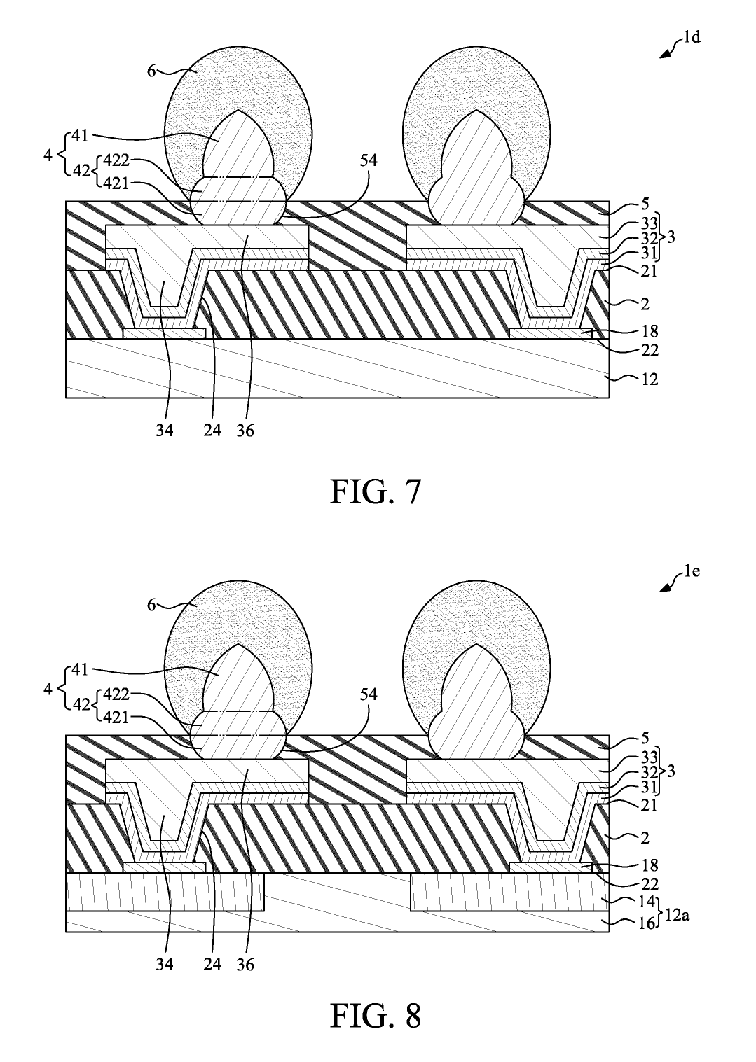

FIG. 7 illustrates a cross sectional view of an electronic device 1d according to some embodiments of the present disclosure. The electronic device 1d is similar to the electronic device 1 shown in FIG. 1 and FIG. 2, except that the electronic device 1d shown in FIG. 7 further includes a base material 12 disposed on the second surface 22 the dielectric layer 2. The base material 12 may include a chip, a wafer or a substrate, and is electrically connected to the redistribution layer 3. For example, the base material 12 may include a pad 18 contacting the conductive via 34 of the redistribution layer 3. Therefore, the redistribution layer 3 is electrically connected to the base material 12 through the conductive via 34 and the pad 18.

FIG. 8 illustrates a cross sectional view of an electronic device 1e according to some embodiments of the present disclosure. The electronic device 1e is similar to the electronic device 1d shown in FIG. 7, except that the base material 12a of the electronic device 1e shown in FIG. 8 includes at least one chip 14 and a molding compound 16. The chip 14 is disposed on the second surface 22 of the dielectric layer 2. The redistribution layer 3 is electrically connected to the chip 14. For example, the chip 14 may include a pad 18 contacting the redistribution layer 3. The molding compound 16 is disposed on the second surface 22 of the dielectric layer 2 and encapsulates the chip 14.

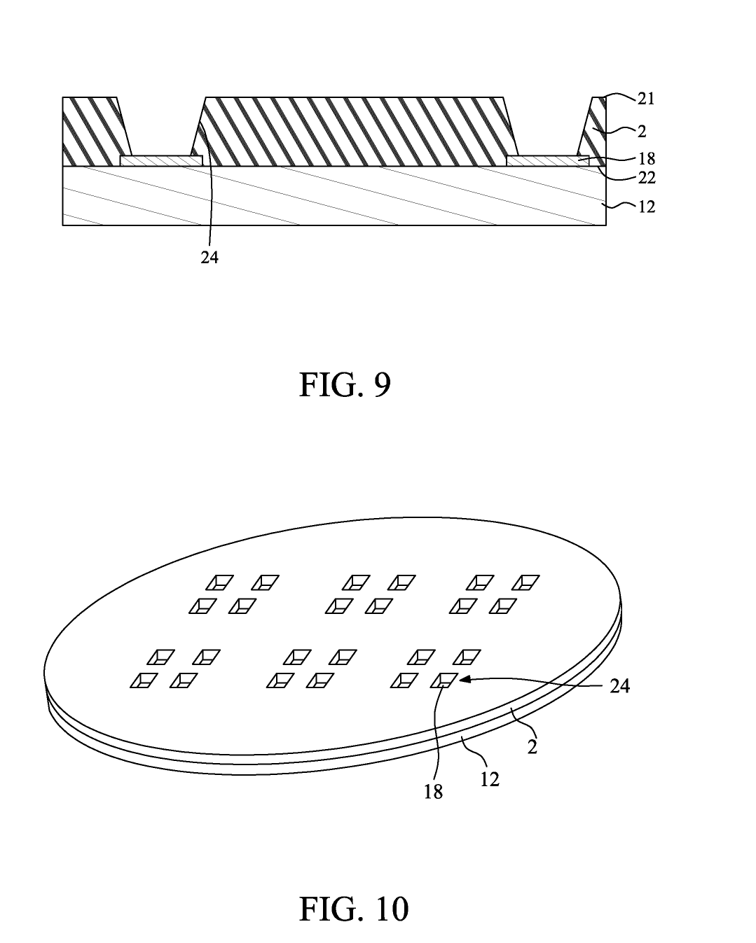

FIG. 9 through FIG. 22 illustrate a method for manufacturing an electronic device according to some embodiments of the present disclosure. In some embodiments, the method is for manufacturing an electronic device such as the electronic device 1d shown in FIG. 7.

Referring to FIG. 9, a base material 12 is provided. The base material 12 may be a chip, a wafer or a substrate, and may include a pad 18. A dielectric layer 2 is formed on the base material 12 and may cover at least a portion of the pad 18. The dielectric layer 2 has a first surface 21 and a second surface 22 opposite to the first surface 21, and defines a through hole 24 extending between the first surface 21 and the second surface 22. A portion of the pad 18 is exposed by the through hole 24 of the dielectric layer 2.

FIG. 10 illustrates a schematic perspective view an example of a combination of the base material 12, the pad 18 and the dielectric layer 2 depicted in FIG. 9 according to some embodiments of the present disclosure. The through hole 24 exposes the pad 18. The shape of the dielectric layer 2 and the base material 12 may be, for example, circular or elliptical.

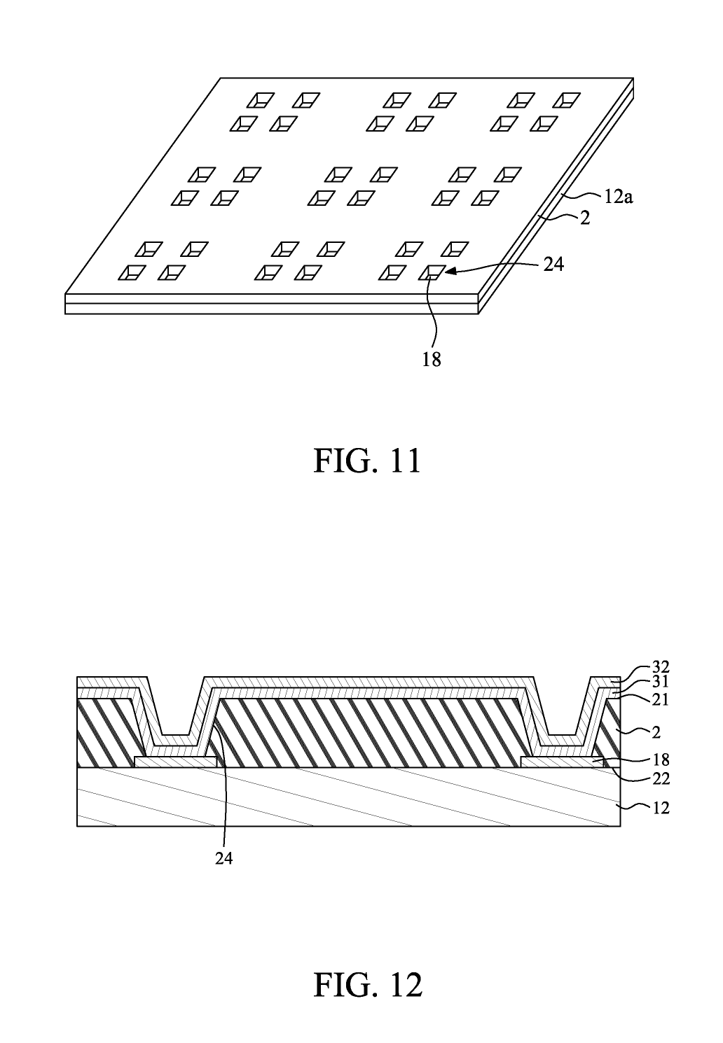

FIG. 11 illustrates a schematic perspective view an example of a combination of the base material 12a, the pad 18 and the dielectric layer 2 depicted in FIG. 9 according to some embodiments of the present disclosure. The through hole 24 exposes the pad 18. The shape of the dielectric layer 2 and the base material 12a may be, for example, rectangular or square.

Referring to FIG. 12, a first metal layer 31 and a second metal layer 32 are sequentially formed on the dielectric layer 2 and in the through hole 24 of the dielectric layer 2. The first metal layer 31 and the second metal layer 32 may be seed layers including, for example, titanium and/or copper, another metal, or an alloy, and may be formed or disposed by sputtering. For example, the first metal layer 31 may include titanium, and the second metal layer 32 may include copper. As shown in FIG. 12, the first metal layer 31 contacts the pad 18 of the base material 12.

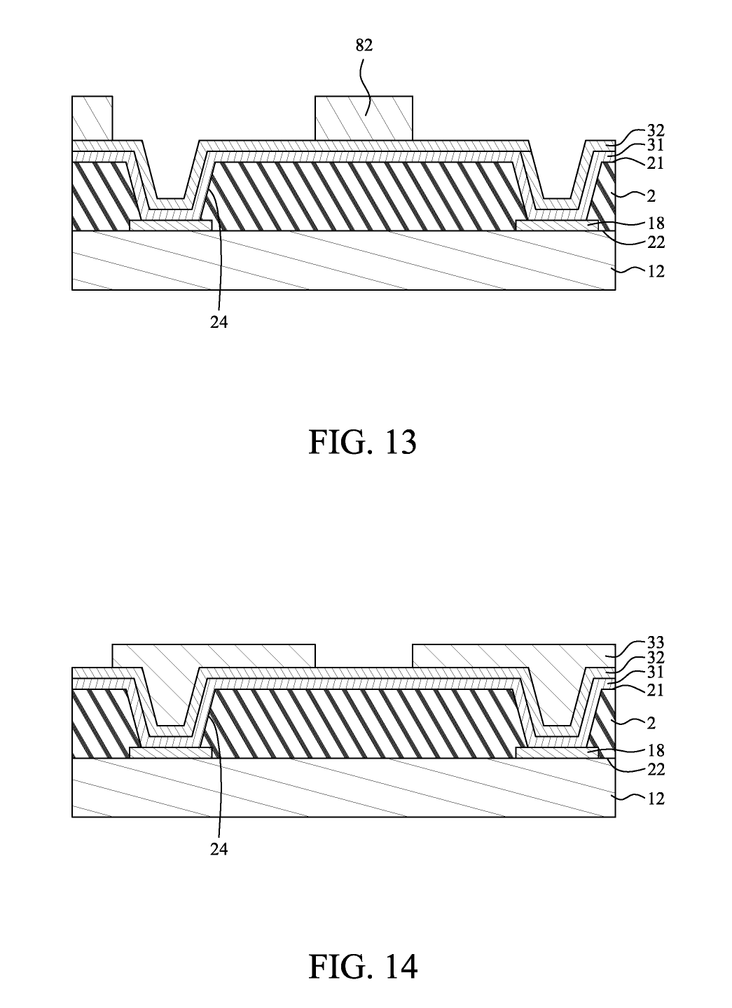

Referring to FIG. 13, a first photoresist 82 is formed on the second metal layer 32. Then, the first photoresist 82 is patterned by, for example, lithography, to expose portions of the second metal layer 32.

Referring to FIG. 14, a third metal layer 33 is formed, for example, by electroplating, in between portions of the first photoresist 82 and on the second metal layer 32. The third metal layer 33 may include, for example, copper, or another metal or combination of metals, and may be formed or disposed by electroplating. Then, the first photoresist 82 is removed, for example, by stripping.

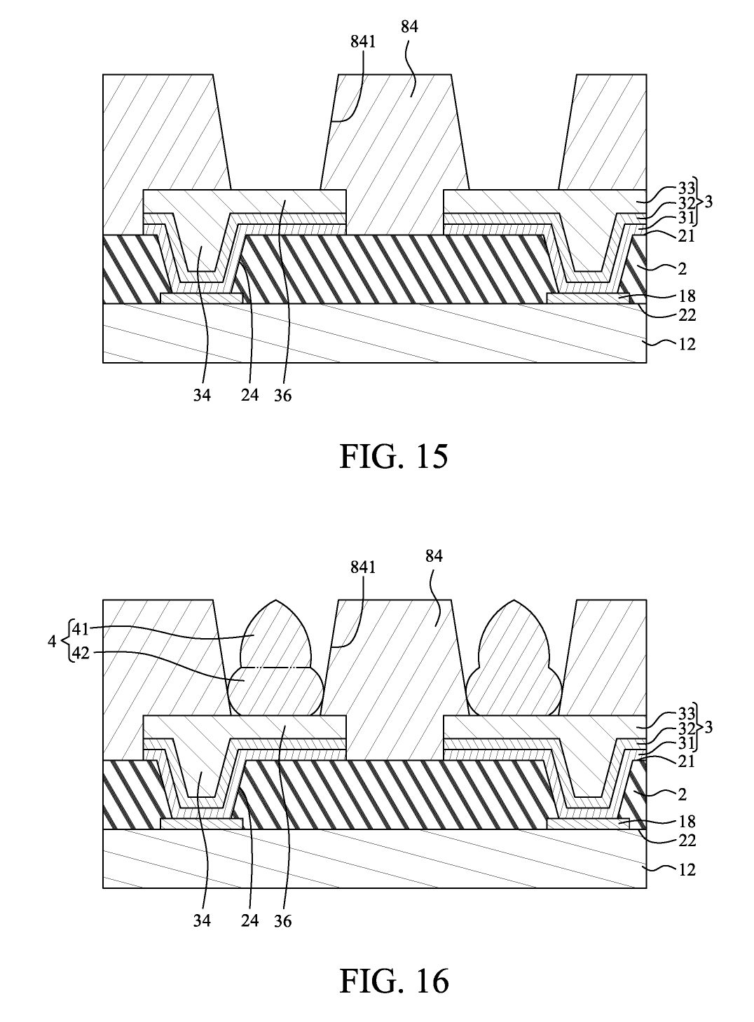

Referring to FIG. 15, portions of the first metal layer 31 and the second metal layer 32 which are not covered by the third metal layer 33 are removed, for example, by etching. Accordingly, a redistribution layer 3 is formed on the dielectric layer 2 and includes the first metal layer 31, the second metal layer 32 and the third metal layer 33. In some embodiments, the redistribution layer 3 may include a conductive via 34 and a bump pad 36. The conductive via 34 may be disposed in the through hole 24 of the dielectric layer 2. The bump pad 36 may be disposed on the second surface 22 of the dielectric layer 2 and electrically connected to the conductive via 34. The redistribution layer 3 is electrically connected to the base material 12. For example, the conductive via 34 is connected to the pad 18 of the base material 12. Then, a patterned second photoresist 84 is formed on the dielectric layer 2 and the redistribution layer 3, for example, by lithography. The second photoresist 84 defines an opening 841, and a portion of the bump pad 36 of the redistribution layer 3 is exposed by the opening 841 of the second photoresist 84.

Referring to FIG. 16, a conductive structure 4 is formed, for example, by a wire-boding process, in the opening 841 of the second photoresist 84 and on the bump pad 36 of the redistribution layer 3. A material of the conductive structure 4 may be a conductive metal, such as, for example, copper and/or gold, or another metal or combination of metals. The conductive structure 4 includes an upper portion 41 and a lower portion 42. The lower portion 42 is disposed on the redistribution layer 3, and the upper portion 41 is disposed on and connected to the lower portion 42. For example, the lower portion 42 of the conductive structure 4 is disposed on and contacts the redistribution layer 3. In some embodiments, the conductive structure 4 is a monolithic structure without a boundary between the upper portion 41 and the lower portion 42 thereof. A volume of the lower portion 42 may be greater than a volume of the upper portion 41 (e.g., may be about 1.1 or more times greater, about 1.2 or more times greater, about 1.3 or more times greater, or about 1.4 or more times greater). In some embodiments, the upper portion 41 is substantially in a cone shape (e.g. a cone having a convex side wall that bulges outwards), and the lower portion 42 is substantially in a disk or puck shape (e.g. a puck having a convex side wall that bulges outwards). For example, the conductive structure 4 may be a stub bump, and the upper portion 41 and the lower portion 42 thereof may respectively be the stud portion and the bump portion of said stud bump.

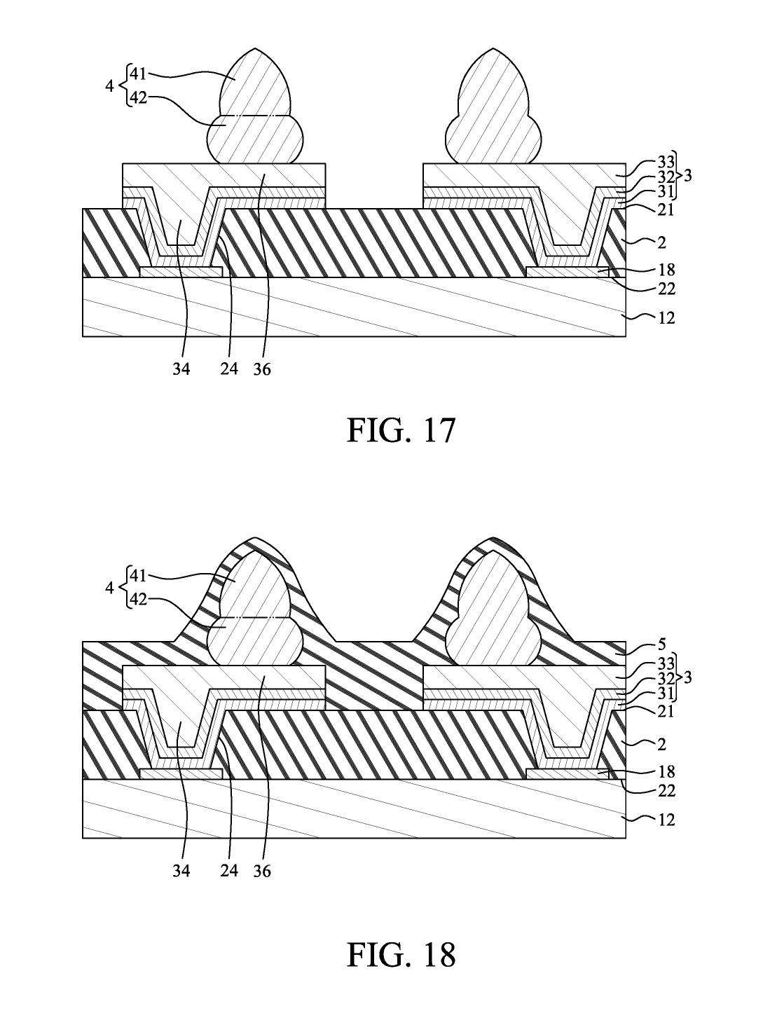

Referring to FIG. 17, the second photoresist 84 is removed, for example, by stripping.

Referring to FIG. 18, an insulating layer 5 is formed on the dielectric layer 2. The insulating layer 5 covers the redistribution layer 3 and the conductive structure 4. The insulating layer 5 may include a PID material such as an epoxy or a PI including photoinitiators.

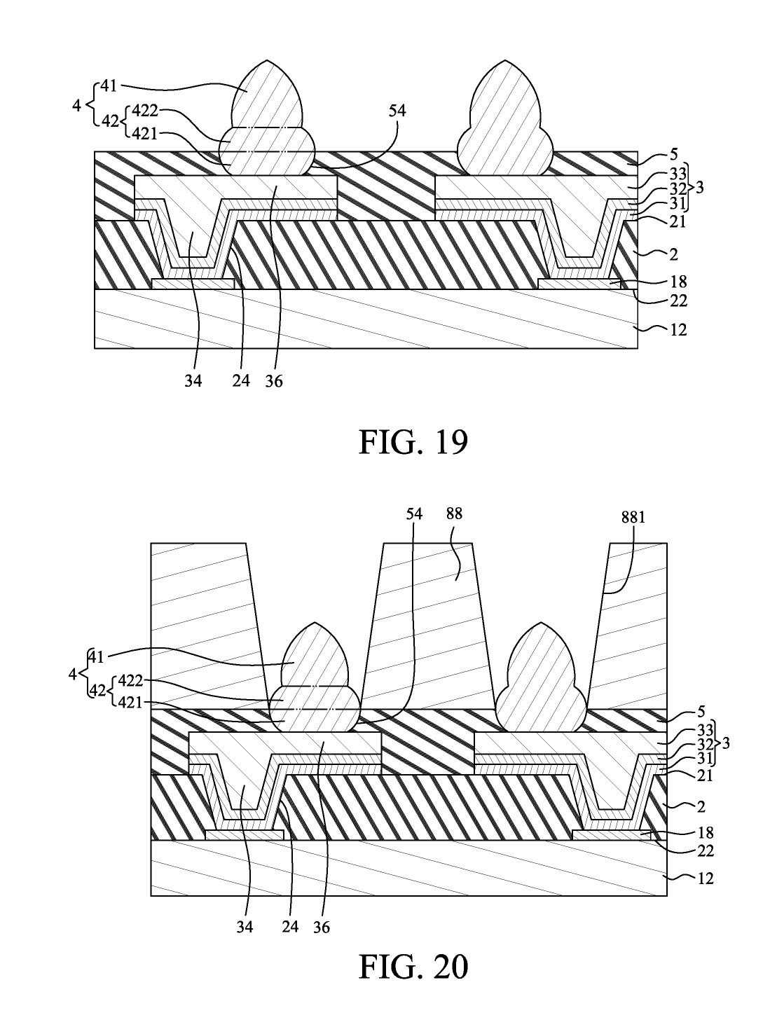

Referring to FIG. 19, the insulating layer 5 on a portion of the conductive structure 4 (e.g. a residue of a material of the insulating layer 5) is removed, for example, by lithography, so as to expose the portion of the conductive structure 4. For example, the insulating layer 5 surrounds a first portion 421 of the lower portion 42 of the conductive structure 4, while a second portion 422 of the conductive structure 4 is exposed. The first portion 421 and the second portion 422 may be divided by an imaginary plane defined by a top surface of the insulating layer 5. The insulating layer 5 defines an accommodating cavity 54 for accommodating the first portion 421 of the lower portion 42 of the conductive structure 4, and a profile of the accommodating cavity 54 is conformal with the first portion 421 of the lower portion 42 of the conductive structure 4. The insulating layer 5 may contact the first portion 421 of the lower portion 42 of the conductive structure 4. For example, the first portion 421 of the lower portion 42 of the conductive structure 4 is embedded in the insulating layer 5. Therefore, the insulating layer 5 can hold the conductive structure 4 securely.

Referring to FIG. 20, a patterned third photoresist 88 is formed on the insulating layer 5. The third photoresist 88 defines an opening 881 corresponding to the conductive structure 4 (e.g. in which the conductive structure 4 is disposed). The conductive structure 4 is exposed by the opening 881 of the third photoresist 88.

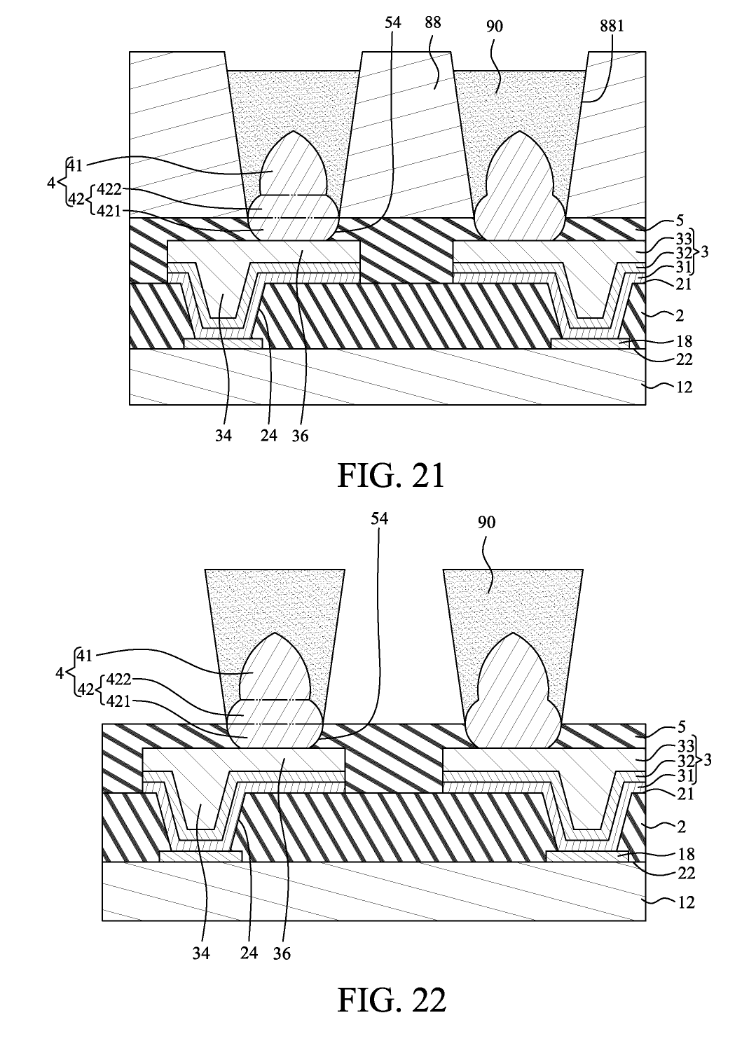

Referring to FIG. 21, a solder material 90 is formed, for example, by plating, in the opening 881 of the third photoresist 88 and on the conductive structure 4. A material of the solder material 90 may be a conductive metal, such as, for example, tin and/or silver, or another metal or combination of metals. The solder material 90 may include a different material from the material of the conductive structure 4.

Referring to FIG. 22, the third photoresist 88 is removed, for example, by stripping. Then, the solder material 90 is melted, for example, by a reflow process, to form a solder ball 6 on the exposed portion of the conductive structure 4. The solder ball 6 covers a portion of the conductive structure 4. Accordingly, the electronic device 1d as shown in FIG. 7 is formed. For example, the solder ball 6 covers the upper portion 41 of the conductive structure 4, and the second portion 422 of the lower portion 42 of the conductive structure 4. In some embodiments, the solder ball 6 does not contact the insulating layer 5.

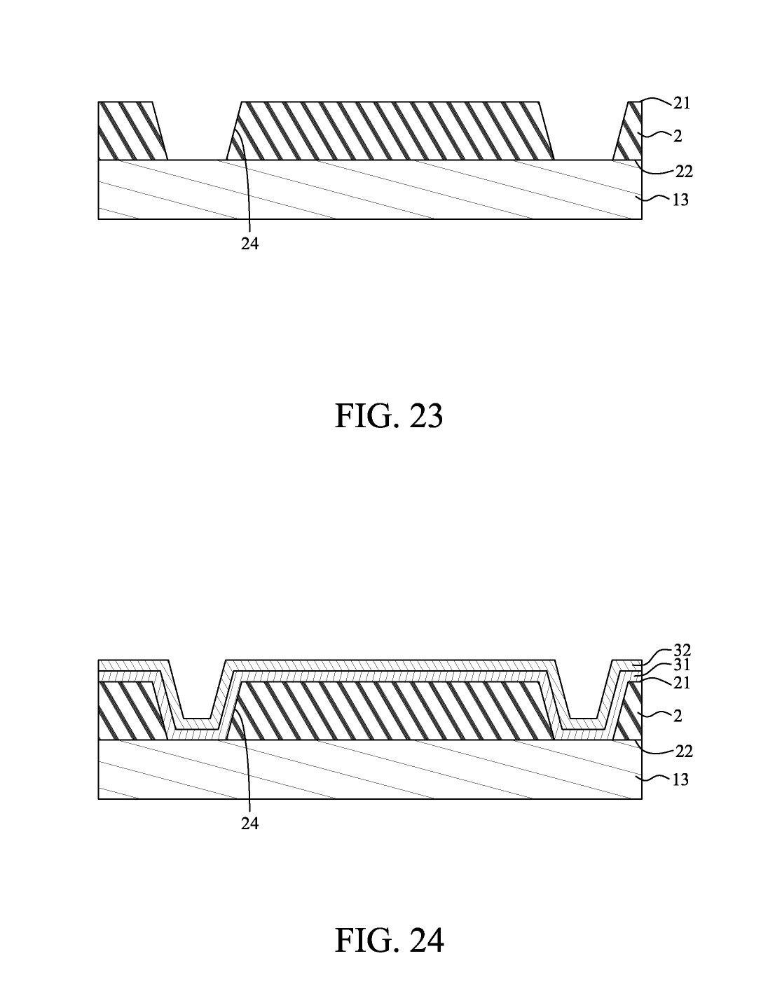

FIG. 23 and FIG. 24 illustrate a method for manufacturing an electronic device according to some embodiments of the present disclosure. In some embodiments, the method is for manufacturing an electronic device such as the electronic device 1 shown in FIG. 1 and FIG. 2. The operations illustrated in FIG. 23 and FIG. 24 may be similar to some operations illustrated in FIG. 9 through FIG. 22.

Referring to FIG. 23, a carrier 13 is provided. Then, a dielectric layer 2 is formed on the carrier 13. The dielectric layer 2 has a first surface 21 and a second surface 22 opposite to the first surface 21, and defines a through hole 24 extending between the first surface 21 and the second surface 22.

Referring to FIG. 24, a first metal layer 31 and a second metal layer 32 are sequentially formed on the dielectric layer 2 and in the through hole 24 of the dielectric layer 2. The first metal layer 31 and the second metal layer 32 may be seed layers including, for example, titanium and/or copper, another metal, or an alloy, and may be formed or disposed by sputtering. For example, the first metal layer 31 may include titanium, and the second metal layer 32 may include copper.

The stages subsequent to those shown in FIG. 24 of the illustrated process can be similar to the stages illustrated in FIG. 13 through FIG. 22. After the reflow process for forming the solder ball 6, the carrier 13 is removed, thus forming the electronic device 1 as shown in FIG. 1 and FIG. 2.

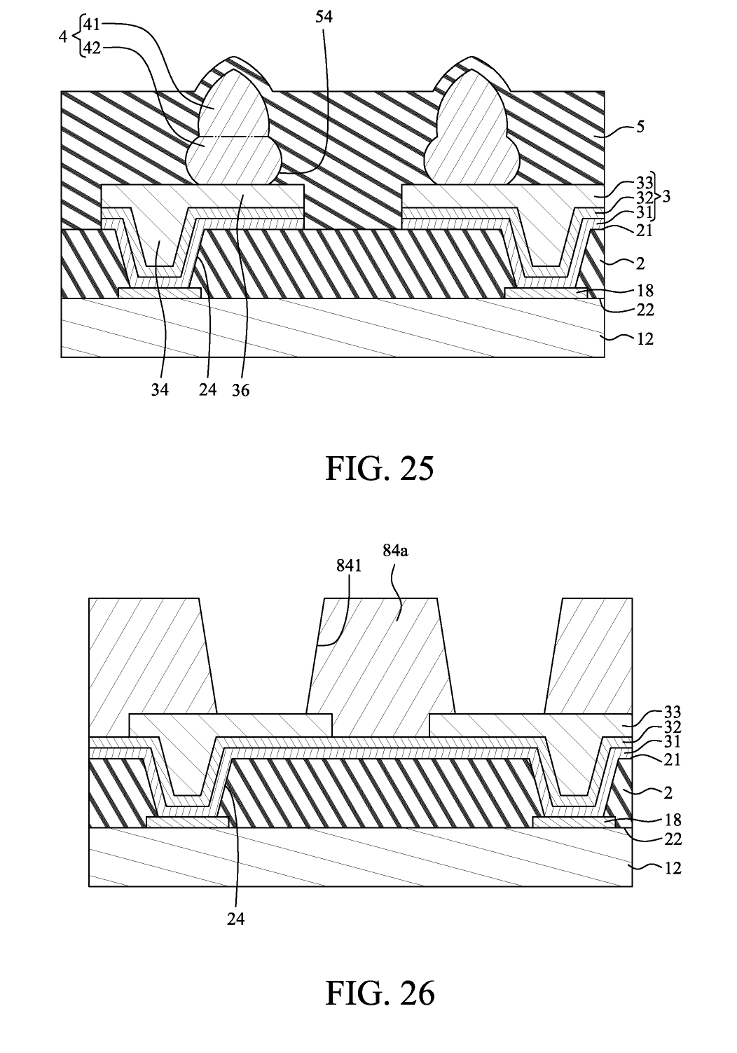

FIG. 25 illustrates a method for manufacturing an electronic device according to some embodiments of the present disclosure. In some embodiments, the method can provide for manufacturing an electronic device such as the electronic device 1d shown in FIG. 7. The initial stages of the illustrated process are the same as, or similar to, the stages illustrated in FIG. 9 through FIG. 17. FIG. 25 depicts a stage subsequent to that depicted in FIG. 17. Referring to FIG. 25, an insulating layer 5 is disposed on and covers the dielectric layer 2, the redistribution layer 3 and the conductive structure 4. The thickness of the insulating layer 5 of FIG. 25 is greater than the thickness of the insulating layer 5 of FIG. 18 (e.g. may have a top surface that has an average height is higher than the lower portion 42 of the conductive structure 4 at all points on the top surface, which may not be the case for some embodiments depicted in FIG. 18). The insulating layer 5 may include an insulating material, such as, for example, BCB based polymer or a PI. Then, a descumming process (e.g., by plasma cleaning) may be conducted to remove a material of the insulating layer 5 on a portion of the conductive structure 4 (e.g. a residue of a material of the insulating layer 5 on the portion of the conductive structure 4), so as to expose the portion of the conductive structure 4. Thus, the insulating layer 5 as shown in FIG. 19 is formed. In some embodiments, the descumming process may also reduce a thickness of the insulating layer 5. The stages subsequent to that shown in FIG. 25 of the illustrated process are similar to the stages illustrated in FIG. 19 through FIG. 22, thus forming the electronic device 1d shown in FIG. 7.

FIG. 26 through FIG. 32 illustrates a method for manufacturing an electronic device according to some embodiments of the present disclosure. In some embodiments, the method can provide for manufacturing an electronic device such as the electronic device 1d shown in FIG. 7. The initial stages of the illustrated process are the same as, or similar to, the stages illustrated in FIG. 9 through FIG. 14. FIG. 26 depicts a stage subsequent to that depicted in FIG. 14.

Referring to FIG. 26, a second photoresist 84a is formed on the second metal layer 32 and on the third metal layer 33, for example, by lithography, while portions of the second metal layer 32 exposed by the third metal layer 33, and portions of the first metal layer 31 underlying those portions of the second metal layer 32, are not yet removed. That is, the first metal layer 31 and the second metal layer 32 are not yet patterned. The second photoresist 84a defines an opening 841, and a portion of the third metal layer 33 is exposed by the opening 841 of the second photoresist 84a.

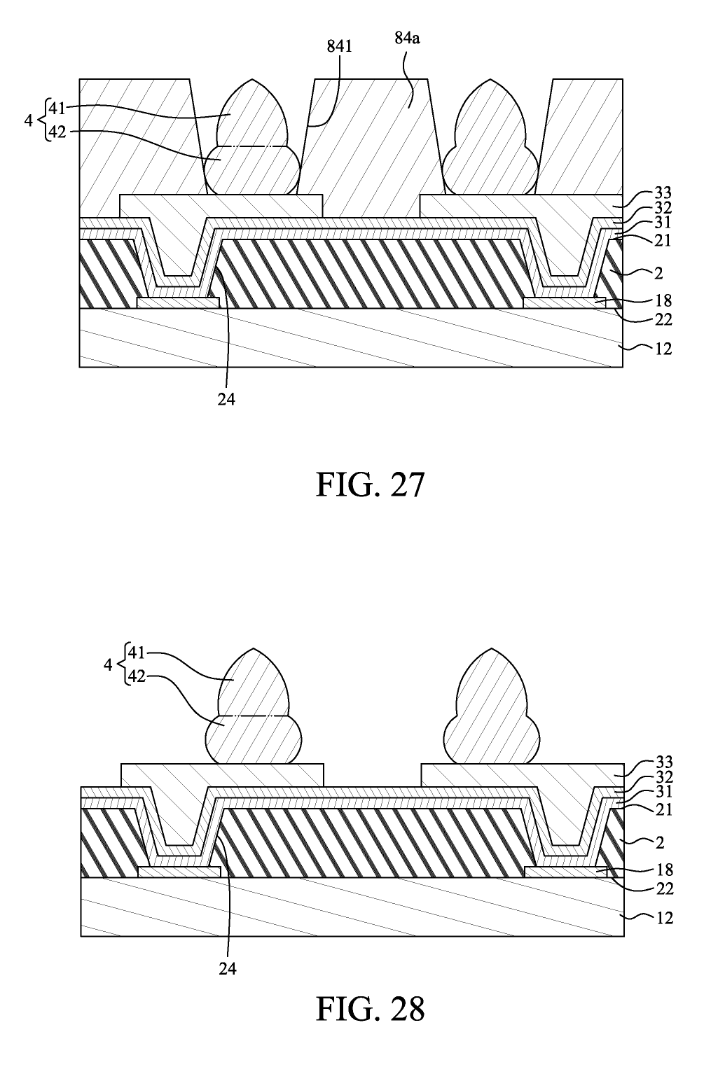

Referring to FIG. 27, a conductive structure 4 is formed, for example, by a wire-boding process, in the opening 841 of the second photoresist 84a and on the third metal layer 33. A material of the conductive structure 4 may be a conductive metal, such as, for example, copper and/or gold, or another metal or combination of metals. The conductive structure 4 includes an upper portion 41 and a lower portion 42. The lower portion 42 is disposed on the third metal layer 33, and the upper portion 41 is disposed on and connected to the lower portion 42. In some embodiments, the conductive structure 4 is a monolithic structure without a boundary between the upper portion 41 and the lower portion 42 thereof. A volume of the lower portion 42 may be greater than a volume of the upper portion 41 (e.g., may be about 1.1 or more times greater, about 1.2 or more times greater, about 1.3 or more times greater, or about 1.4 or more times greater). In some embodiments, the upper portion 41 is substantially in a cone shape (e.g. a cone having a convex side wall that bulges outwards), and the lower portion 42 is substantially in a disk or puck shape (e.g. a puck having a convex side wall that bulges outwards). For example, the conductive structure 4 may be a stub bump, and the upper portion 41 and the lower portion 42 thereof may respectively be the stud portion and the bump portion of said stud bump.

Referring to FIG. 28, the second photoresist 84a is removed, for example, by stripping.

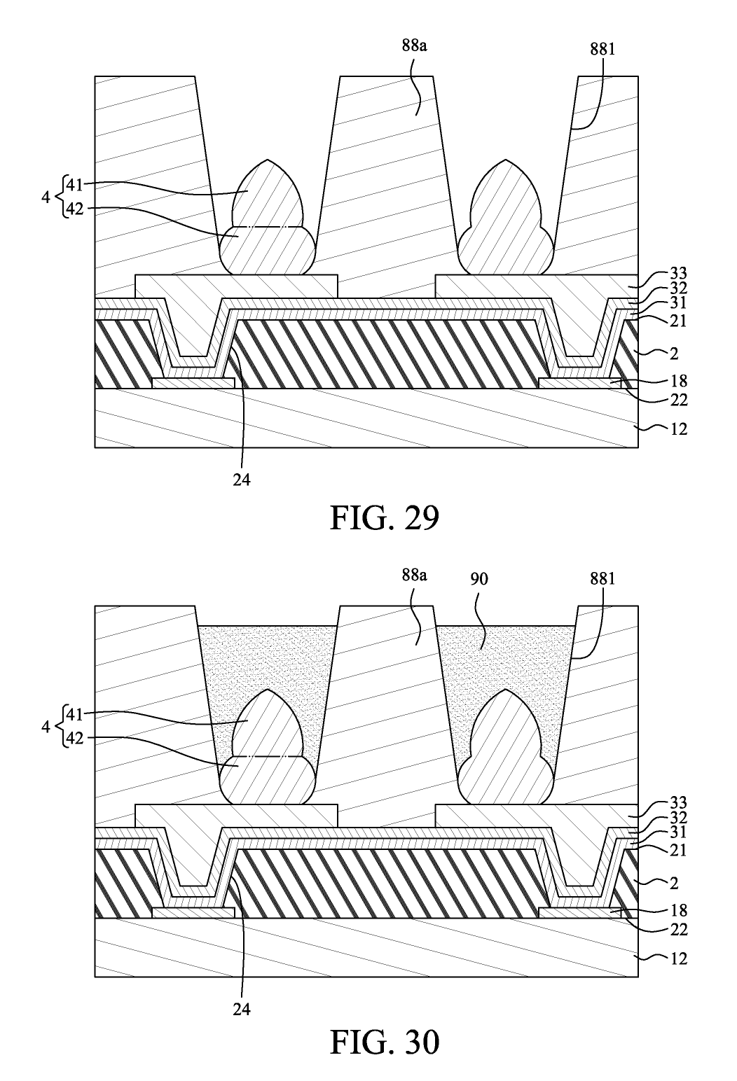

Referring to FIG. 29, a third photoresist 88a is formed on the second metal layer 32 and on the third metal layer 33. The third photoresist 88a defines an opening 881 corresponding to the conductive structure 4. The conductive structure 4 is exposed by the opening 881 of the third photoresist 88a.

Referring to FIG. 30, a solder material 90 is formed, for example, by plating, in the opening 881 of the third photoresist 88a and on the conductive structure 4. A material of the solder material 90 may be a conductive metal, such as, for example, tin and/or silver, or another metal or combination of metals. The material of the solder material 90 may be different from a material of the conductive structure 4.

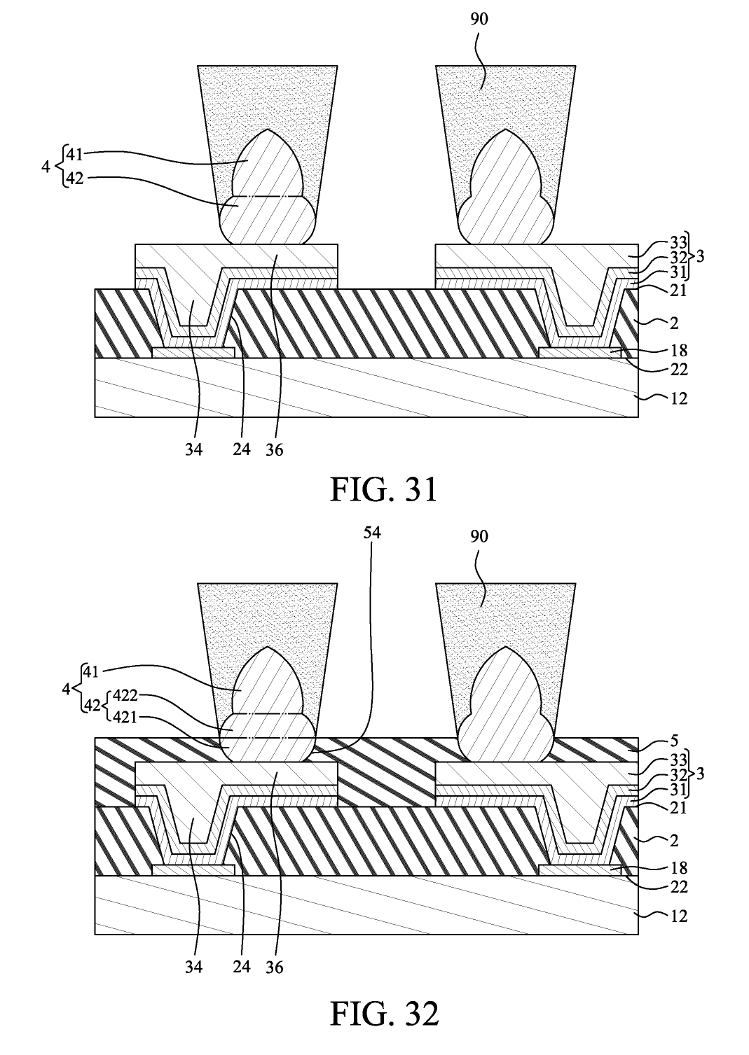

Referring to FIG. 31, the third photoresist 88a is removed, for example, by stripping. Then, the portions of the first metal layer 31 and the second metal layer 32 which are not covered by the third metal layer 33 are removed, for example, by etching. Accordingly, a redistribution layer 3 is formed on the dielectric layer 2 and includes the first metal layer 31, the second metal layer 32 and the third metal layer 33. In some embodiments, the redistribution layer 3 may include a conductive via 34 and a bump pad 36. The conductive via 34 may be disposed in the through hole 24. The bump pad 36 may be disposed on the second surface 22 of the dielectric layer 2 and electrically connected to the conductive via 34. The conductive structure 4 may be disposed on the bump pad 36 of the redistribution layer 3.

Referring to FIG. 32, an insulating layer 5 is formed on the dielectric layer 2. The insulating layer 5 covers the redistribution layer 3 and the conductive structure 4, while a portion of the conductive structure 4 is exposed from the insulating layer 5. For example, the insulating layer 5 covers a first portion 421 of the lower portion 42 of the conductive structure 4, while a second portion 422 of the conductive structure 4 is exposed from the insulating layer 5 (and, for example, covered by the solder material 90). The insulating layer 5 may include an insulating material, such as, for example, BCB based polymer or a PI. In some embodiments, the insulating layer 5 may include cured PID material such as an epoxy or a PI including photoinitiators. The insulating layer 5 defines an accommodating cavity 54 for accommodating the portion 421 of the lower portion 42 of the conductive structure 4, and a profile of the accommodating cavity 54 is conformal to the portion 421 of the lower portion 42 of the conductive structure 4. The insulating layer 5 may contact the portion 421 of the lower portion 42 of the conductive structure 4. For example, the portion 421 of the lower portion 42 of the conductive structure 4 is embedded in the insulating layer 5. Then, the solder material 90 is melted, for example, by a reflow process, to form a solder ball 6 on the exposed portion of the conductive structure 4. Accordingly, the electronic device 1d as shown in FIG. 7 is formed. The solder ball 6 covers a portion of the conductive structure 4. For example, the solder ball 6 covers the upper portion 41 of the conductive structure 4, and the second portion 422 of the lower portion 42 of the conductive structure 4. In some embodiments, the solder ball 6 does not contact the insulating layer 5.

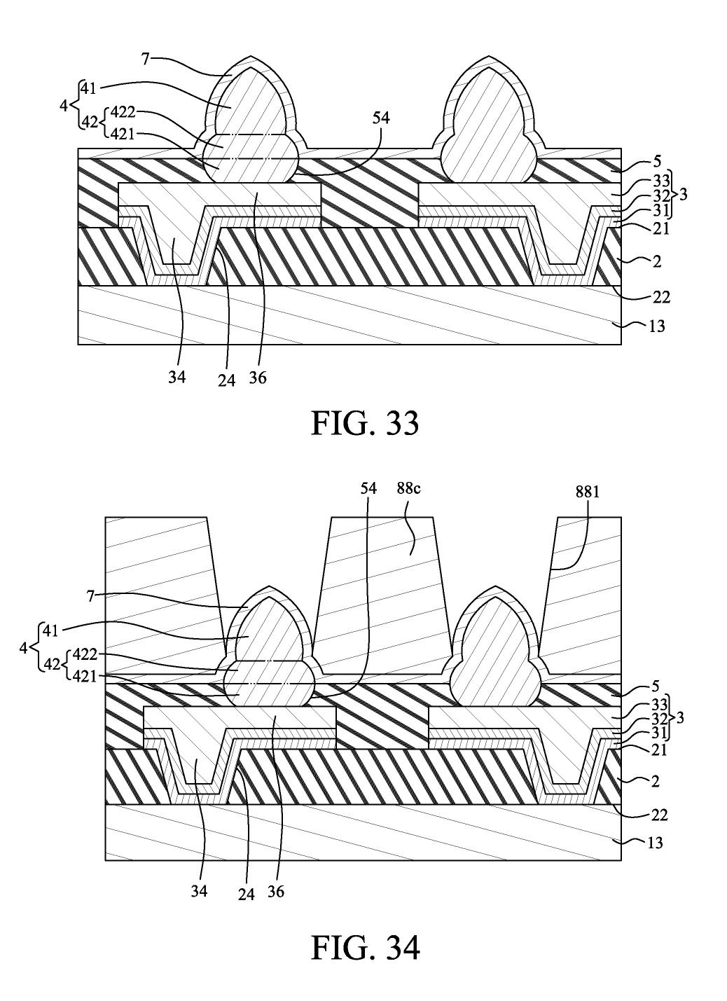

FIG. 33 through FIG. 36 illustrates a method for manufacturing an electronic device according to some embodiments of the present disclosure. In some embodiments, the method provides for manufacturing an electronic device such as the electronic device 1b shown in FIG. 4 and FIG. 5. The initial stages of the illustrated process are the same as, or similar to, the stages illustrated in FIG. 23, FIG. 24, and FIG. 13 through FIG. 19. FIG. 33 depicts a stage subsequent to that depicted in FIG. 19.

Referring to FIG. 33, a seed layer 7 is formed on the insulating layer 5 and on the conductive structure 4. For example, the seed layer 7 covers an exposed portion of the conductive structure 4 (e.g., the upper portion 41 of the conductive structure 4 and the second portion 422 of the lower portion 42 of the conductive structure 4).

Referring to FIG. 34, a third photoresist 88c is formed on the insulating layer 5. The third photoresist 88c defines an opening 881 in which the conductive structure 4 is disposed. The conductive structure 4 is exposed by the opening 881 of the third photoresist 88c.

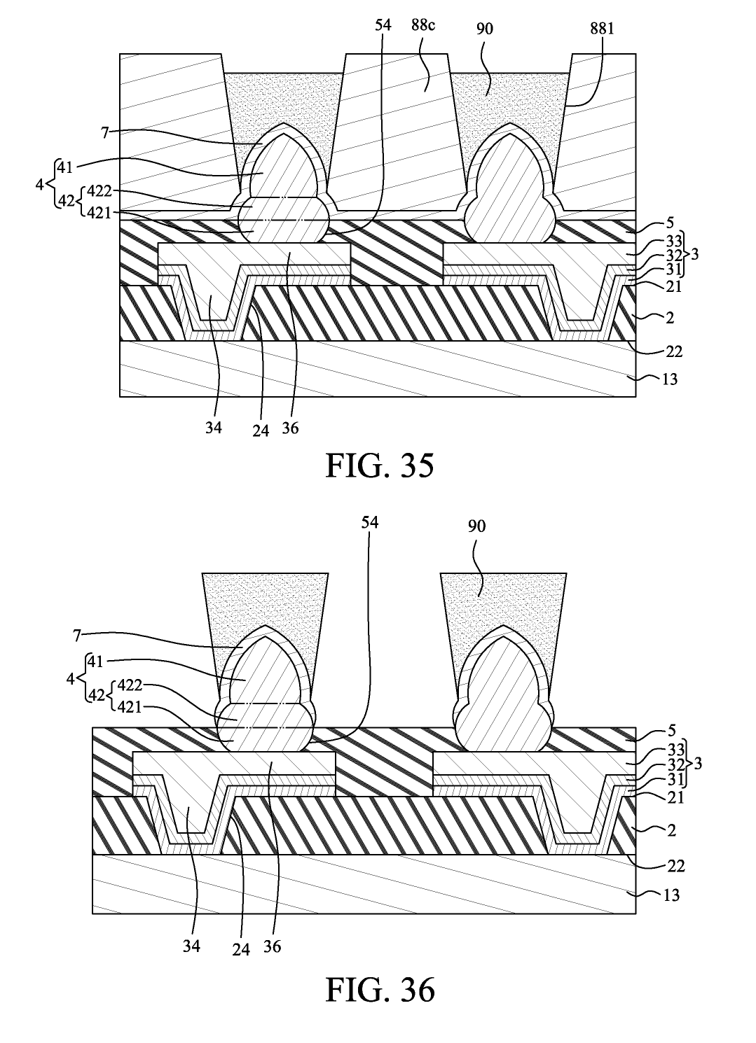

Referring to FIG. 35, a solder material 90 is formed, for example, by plating, in the opening 881 of the third photoresist 88c and on the conductive structure 4. A material of the solder material 90 may be a conductive metal, such as, for example, tin and/or silver, or another metal or combination of metals. The material of the solder material 90 may be different from a material of the conductive structure 4.

Referring to FIG. 36, the third photoresist 88c is removed, for example, by stripping. Then, a portion of the seed layer 7 which is disposed on the insulating layer 5 is removed, for example, by etching. After the etching process, the seed layer covers a portion of the conductive structure 4. For example, the seed layer covers the upper portion 41 of the conductive structure 4, and the second portion 422 of the lower portion 42 of the conductive structure 4. Then, the solder material 90 is melted, for example, by a reflow process, to form a solder ball 6 on the seed layer 7 and covers a portion of the conductive structure 4. For example, the solder ball 6 also covers the upper portion 41 of the conductive structure 4, and the portion 422 of the lower portion 42 of the conductive structure 4. Then, the carrier 13 is removed, thus forming the electronic device 1b as shown in FIG. 4 and FIG. 5. The seed layer 7 is disposed between the conductive structure 4 and the solder ball 6. For example, the seed layer 7 may be covered by the solder ball 6 (e.g. completely covered by the solder ball 6). In some embodiments, the solder ball 6 does not contact the insulating layer 5.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. An electronic device, comprising:
a dielectric layer having a first surface and a second surface opposite to the first surface, and defining a through hole extending between the first surface and the second surface;
a redistribution layer disposed on the first surface of the dielectric layer and in the through hole;
a conductive structure disposed on the redistribution layer, wherein the conductive structure includes an upper portion and a lower portion, the upper portion has a cone shape and has a convex side wall that bulges outwards, the lower portion has a disk shape and has a convex side wall that bulges outwards, the lower portion is disposed on the redistribution layer, and the upper portion is disposed on the lower portion;
an insulating layer covering a portion of the redistribution layer and surrounding a first portion of the lower portion of the conductive structure; and
a solder bump covering a portion of the conductive structure.

2. The electronic device of claim 1, wherein a volume of the lower portion of the conductive structure is greater than a volume of the upper portion of the conductive structure.

3. (canceled)

4. The electronic device of claim 1, wherein a height of the first portion of the lower portion of the conductive structure surrounded by the insulating layer is equal to or greater than a half of a total height of the lower portion of the conductive structure.

5. The electronic device of claim 1, wherein a maximum width of the lower portion of the conductive structure is in a range of about 15 micrometers (μm) to about 70 μm, and a height of the lower portion of the conductive structure is in a range of about 6.4 μm to about 30 μm.

6. The electronic device of claim 1, wherein a ratio of a maximum width of the lower portion of the conductive structure to a height of the lower portion of the conductive structure is in a range of about 1.5 to about 3.

7. The electronic device of claim 1, wherein a material of the conductive structure is different from a material of the solder bump.

8. The electronic device of claim 1, wherein the insulating layer includes a polyimide (PI) or benzocyclobutene (BCB) based polymer.

9. The electronic device of claim 1, wherein the insulating layer defines an accommodating cavity for accommodating at least the first portion of the lower portion of the conductive structure, and a profile of the accommodating cavity is conformal to the first portion of the lower portion of the conductive structure.

10. The electronic device of claim 1, wherein the solder bump covers the upper portion of the conductive structure.

11. The electronic device of claim 1, wherein the solder bump covers the upper portion and a second portion of the lower portion of the conductive structure.

12. The electronic device of claim 11, wherein a height of the second portion of the lower portion of the conductive structure covered by the solder ball is substantially equal to a half of a total height of the lower portion of the conductive structure.

13. The electronic device of claim 11, wherein a height of the second portion of the lower portion of the conductive structure covered by the solder ball is less than a half of a total height of the lower portion of the conductive structure.

14. The electronic device of claim 1, further comprising a seed layer at least partially covering the conductive structure.

15. The electronic device of claim 14, wherein the seed layer covers the upper portion and a second portion of the lower portion of the conductive structure.

16. The electronic device of claim 1, further comprising a base material disposed on the second surface the dielectric layer, wherein the base material includes a chip, a wafer or a substrate, and the redistribution layer is electrically connected to the base material.

17. A method for manufacturing an electronic device, comprising:
(a) forming a dielectric layer;
(b) forming a redistribution layer on the dielectric layer;
(c) forming a conductive structure on the redistribution layer;
(d) forming an insulating layer to cover the conductive structure and the redistribution layer, wherein a portion of the conductive structure is exposed from the insulating layer; and
(e) forming a solder bump on the exposed portion of the conductive structure.

18. The method of claim 17, wherein in (a), the dielectric layer is formed on a carrier, and after (e), the method further comprises removing the carrier.

19. The method of claim 17, wherein in (a), the dielectric layer is formed on a base material, and the base material includes a chip, a wafer or a substrate; and in (b), the redistribution layer is electrically connected to the base material.

20. The method of claim 17, wherein in (c), the conductive structure is formed by a wire-bonding process.

21. The method of claim 17, wherein in (c), the conductive structure is a monolithic structure.

22. The method of claim 17, wherein before (e), the method further forming a seed layer on a portion of the conductive structure.

23. The method of claim 17, wherein in (d), the method further comprises removing a residue of a material of the insulating layer on a portion of the conductive structure so as to expose the portion of the conductive structure.
